(19) United States
(12) Patent Application Publication
(10) Pub. No.: US 2026/0271659 A1
(43) Pub. Date: Sep. 10, 2026

(54) THIN FILM THICKNESS AND NON-UNIFORMITY MONITORING

(71) Applicant: Applied Materials, Inc., Santa Clara, CA (US)

(72) Inventors: USMAN CHOWDHURY, Santa Clara, CA (US); SHUBH KUMAR JAIN, Tempe, AZ (US); KASTURI SARANG, San Jose, CA (US); RU JIA, San Jose, CA (US); AMIR BAYATI, San Jose, CA (US)

(21) Appl. No.: 19/071,639

(22) Filed: Mar. 5, 2025

(51) Int. Cl. H01L 21/67; G06N 20/00

(52) U.S. Cl. CPC H10P 72/0604; G06N 20/00; H10P 72/0602

(57) ABSTRACT

Embodiments described herein relate to a method that includes obtaining a training data set for a film deposition process, where the training data set includes a plurality of film thickness values and a plurality of sensor data sets. In an embodiment, each of the plurality of sensor data sets correspond to a different one of the plurality of film thickness values. In an embodiment, the method further includes generating a model from the training data set, where the model outputs a film thickness value when a sensor data set is input into the model. In an embodiment, the method may further include testing the model with a testing data set.

### BACKGROUND

### 1) Field

Embodiments of the present disclosure pertain to the field of thin film monitoring through machine learning based metrology analysis in semiconductor manufacturing processes.

### 2) Description of Related Art

The fabrication of microelectronic devices, display devices, micro-electromechanical systems (MEMS), and the like require the use of one or more processing chambers. For example, processing chambers such as, but not limited to, an atomic layer deposition chamber, a chemical vapor deposition chamber, a physical vapor deposition chamber, or a plasma treatment chamber may be used to fabricate various devices. As scaling continues to drive to smaller critical dimensions in such devices, the need for uniform processing conditions (e.g., uniformity across a single substrate, uniformity between different lots of substrates, and uniformity between chambers in a facility) as well as process stability during the process are becoming more critical in high volume manufacturing (HVM) environments.

Metrology may be used in order to confirm uniformity of various processing outcomes. For example, a spectrometer may be used to measure a thickness of a film deposited over a substrate. Metrology processes typically include taking a substrate off of the production line in order to inspect the substrate with a dedicated metrology tool. Metrology processes can also be time intensive, which can have a negative impact on the throughput.

### SUMMARY

Embodiments described herein relate to a method that includes obtaining a training data set for a film deposition process, where the training data set includes a plurality of film thickness values and a plurality of sensor data sets. In an embodiment, each of the plurality of sensor data sets correspond to a different one of the plurality of film thickness values. In an embodiment, the method further includes generating a model from the training data set, where the model outputs a film thickness value when a sensor data set is input into the model. In an embodiment, the method may further include testing the model with a testing data set.

Embodiments described herein relate to a method that includes obtaining a training data set for a film deposition process, wherein the training data set includes a plurality of film thickness uniformity values, and a plurality of sensor data sets, where each of the plurality of sensor data sets includes a plurality of standard deviations of sensor readings, and where each of the plurality of sensor data sets correspond to a different one of the plurality of film thickness uniformity values. In an embodiment, the method may further include generating a model from the training data set, where the model outputs a film thickness uniformity when a sensor data set is input into the model.

Embodiments described herein relate to a method that includes depositing a film on a substrate in a chamber of a tool, and recording sensor data produced by a plurality of sensors configured to measure a plurality of parameters of the tool while depositing the film on the substrate. In an embodiment, the method further includes inputting the sensor data into a model generated with machine learning in order to calculate a film property.

### BRIEF DESCRIPTION OF THE DRAWINGS

FIG. 1A is a cross-sectional illustration of a substrate with a film deposited over a surface of the substrate, in accordance with an embodiment.

FIG. 1B is a cross-sectional illustration of a substrate with a film with high non-uniformity deposited over a surface of the substrate, in accordance with an embodiment.

FIG. 2 is a cross-sectional illustration of a deposition chamber for depositing a film over a substrate, in accordance with an embodiment.

FIG. 3 is a schematic illustration of an ampoule for holding a precursor, in accordance with an embodiment of the present disclosure.

FIG. 4A is a schematic illustration of a photonic sensor, in accordance with an embodiment of the present disclosure.

FIG. 4B is a schematic illustration of a photonic sensor with a plurality integrated temperature sensors for enabling dynamic correction for leakage current and/or background radiation, in accordance with an embodiment of the present disclosure.

FIG. 5A is a plot of a raw data from a data set relating precursor dose to thickness, in accordance with an embodiment.

FIG. 5B is a plot of effective dose to thickness when a linear model is applied to the data set, in accordance with an embodiment.

FIG. 5C is a plot of effective dose to thickness when a model generated through a machine learning algorithm is applied to the data set, in accordance with an embodiment.

FIG. 6 is a flow diagram depicting a process for generating a model that predicts film thickness in response to a plurality of sensor values that are input into the model, in accordance with an embodiment.

FIG. 7 is a flow diagram depicting a process for generating a model that predicts film thickness uniformity in response to standard deviations of a plurality of sensor values that are input into the model, in accordance with an embodiment.

FIG. 8A is a flow diagram for implementing virtual metrology to monitor a film thickness property using a machine learning generated model that associates sensor readings from a plurality of sensors to the film thickness property, in accordance with an embodiment.

FIG. 8B is a plot of a target thickness with offset thresholds for triggering further investigation into film properties, in accordance with an embodiment.

FIG. 9 illustrates a block diagram of an exemplary computer system of a processing tool, in accordance with an embodiment of the present disclosure.

### DETAILED DESCRIPTION

Described herein are systems and methods for thin film monitoring through virtual metrology in semiconductor manufacturing processes. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

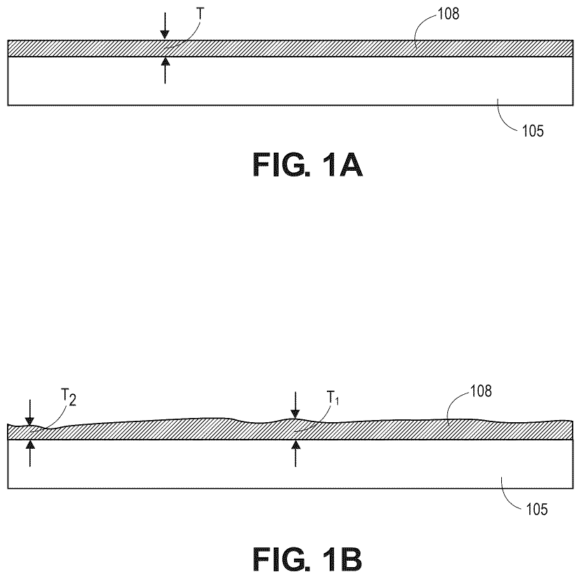

As noted above, process uniformity and process control are key metrics for semiconductor processing. In deposition processes (e.g., atomic layer deposition (ALD), chemical vapor deposition (CVD), etc.), control of film thickness and film thickness uniformity across a substrate are important metrics in order to provide high yielding processes. For example, in FIG. 1A, a film 108 is deposited over a substrate 105 (e.g., a semiconductor wafer or the like). In an embodiment a measurement of the thickness T of the film may be an important metric in order to build high yielding devices on the substrate 105. As films 108 continue to scale to smaller thicknesses (e.g., nanometer scale or even sub-nanometer scale (e.g., tens of angstroms)), the ability to control of the thickness T is heightened. In addition to film thickness T, good thickness uniformity across the substrate 105 is needed in order to provide uniform properties to the many devices fabricated on the substrate. For example, in FIG. 1B the film 108 has poor thickness uniformity as indicated by differences in the thicknesses T₁ at a center of the substrate 105 and the thickness T₂ at an edge of the substrate 105.

Currently, such deposition processes are monitored through the use of physical metrology. However, physical metrology is a time intensive process and results in a lower overall throughput. Additionally, when physical metrology is used, not all substrates can be inspected. As such, multiple substrates may be processed before errors in the deposition process are detected.

Accordingly, interest in developing virtual metrology solutions is growing. A virtual metrology solution may include the use of a model in order to predict the resulting film thickness properties. One option for producing a virtual metrology model is the use of a physics based model. In a physics based model, the equations and/or modeling for physics based and chemical based interactions of the deposition process are used to calculate the film thickness properties. However, such a model would be incredibly complex due to the many interactions within the system. As such, the accuracy and reliability of such a physics based model may be suboptimal. Additionally, such a model would be computationally intensive, which makes real-time or near real-time calculation impractical.

As such, embodiments disclosed herein may include the development and utilization of a machine learning based model in order to provide more accurate and faster film thickness virtual metrology readings. For example, a data set comprising thickness values that are each associated with a plurality of sensor readings can be used to train a model. After the model is trained and validated, the model may be employed in production in order to calculate film thickness properties through virtual metrology. This allows for every substrate to be monitored without an impact to throughput.

In some embodiments, the thickness values may include a measure of the thickness. For example, the readings from a plurality of sensors coupled to a processing tool may be used as an input into the model, and the measure of thickness is an output of the model. In other embodiments, the thickness values may include a thickness uniformity value. Thickness uniformity values may be determined by inputting standard deviations of sensor readings into the model. The thickness values outputted by the model may be compared to threshold values in order to determine if the processing outcomes are being met. When threshold values are exceeded, the substrate may be examined with further physical metrology, changes to the processing parameters may be made, and/or maintenance to the tool may be initiated.

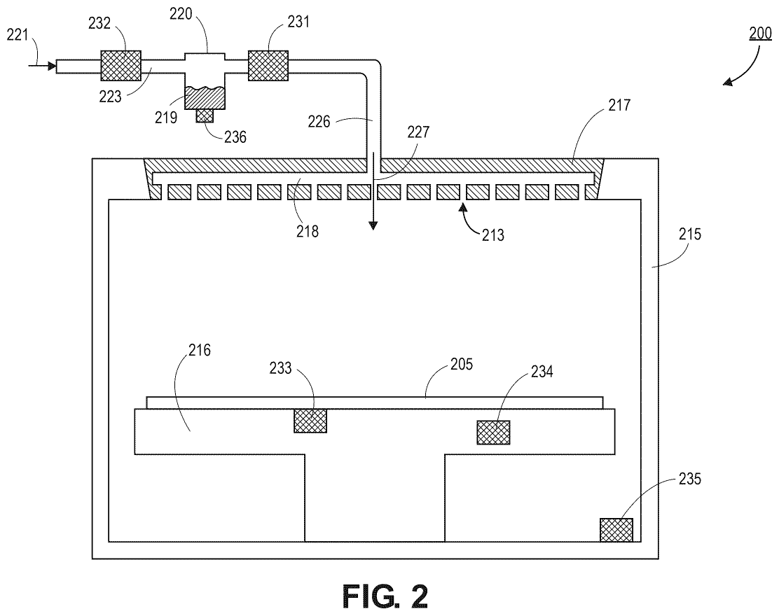

Referring now to FIG. 2, a cross-sectional illustration of a tool 200 for depositing a film on a substrate 205 is shown, in accordance with an embodiment. In an embodiment, the tool may be an ALD tool, a plasma enhanced ALD tool, a CVD tool, a plasma enhanced CVD tool, or the like. In an embodiment, the tool 200 may also include a chamber 215, such as a vacuum chamber. The substrate 205 may be supported by a chuck 216, a pedestal, or the like. In an embodiment, a precursor gas 227 may be flown into the chamber 215 through a gas distribution shower head 217 or the like. For example, the precursor gas 227 may be flown into a plenum 218 of the shower head 217, and into the chamber 215 through gas outlets 213.

In an embodiment, the precursor gas 227 may comprise a processing gas and a carrier gas 221. For example, the carrier gas 221 may be flown into an ampoule 220 through gas line 223. A precursor liquid 219 may be provided in the ampoule 220. Vapor from the precursor liquid 219 (i.e., the processing gas) may mix with the carrier gas 221 in order to form the precursor gas 227 that is delivered to the chamber 215 through the gas line 226.

In order to provide the input values for the model used to implement the virtual metrology, a plurality of sensors are coupled to the tool 200. In the illustrated embodiment, six sensors 231-236 are coupled to the tool 200. Though, embodiments may include any number of sensors (e.g., ten or more sensors, twenty or more sensors, or the like). In an embodiment, the first sensor 231 may be a photonic sensor used to measure a concentration of species of the processing gas. As can be appreciated, the concentration of species of the processing gas in the precursor gas 227 is a key driver of the thickness of the film that is deposited on the substrate 205. As will be described in greater detail herein, the design and operation of the first sensor 231 for measuring the concentration of species is complicated due to temperature dependencies of various elements of the ampoule and photonic sensor. Further, the ability to provide good accuracy of the concentration of species in the precursor gas 227 will provide better results from the model. In an embodiment, the first sensor 231 may comprise a non-dispersive infrared (NDIR) optical absorption sensor.

In an embodiment, a second sensor 232, such as a gas flow sensor, may be coupled to the tool 200 to measure a volume of the carrier gas 221 that is flown into the chamber 215. In an embodiment, a third sensor 233, such as a gas flow sensor, may be coupled to the tool 200 to measure a flow of a backside gas (e.g., helium) that is provided to a backside of the substrate 205 during the deposition process. In an embodiment, a fourth sensor 234, such as a temperature sensor, may be coupled to the tool 200 to measure a temperature of the chuck 216 during the deposition process. In an embodiment, a fifth sensor 235, such as a pressure sensor, may be coupled to the tool 200 to measure a pressure within the chamber 215 during the deposition process. In an embodiment, a sixth sensor 236, such as a temperature sensor, may be coupled to the tool to measure a temperature of the ampoule 220 during the deposition process.

To provide further context, existing sensors for species concentration measurement for the precursor gas 227 suffer from poor signal to noise ratio (SNR), and are unable to differentiate changes in process conditions or drift. Processes can benefit from a more sensitive photonic sensor that can operate at the low pressures, high temperatures, and low concentrations (<1 mol %) typical of semiconductor processes.

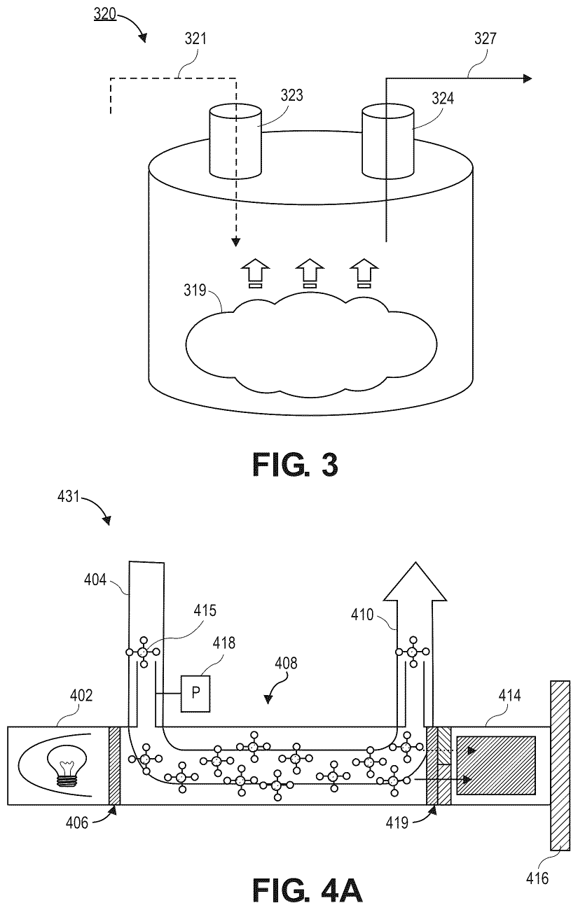

As can be appreciated, chemical precursors have complex delivery characteristics. FIG. 3 illustrates a schematic of an ampoule 320 for holding a volatile precursor 319, in accordance with an embodiment of the present disclosure. Though, it is to be appreciated that non-volatile precursors may also be used in accordance with different embodiments disclosed herein. In an embodiment, the ampoule 320 includes a carrier gas 321 inlet 323, a storage area for a volatile precursor 319, and a carrier gas/precursor outlet 324. As a carrier gas 321 is flown into the ampoule 320 through the carrier gas inlet 323, the volatile precursor 319 is mixed and “carried” with the carrier gas 321 out of the gas/precursor outlet 324 as a precursor gas 327. It is to be appreciated that the amount of the volatile precursor 319 that is removed from the ampoule 320 is dependent on many factors, such as, but not limited to, the flow rate of the carrier gas 321 and/or a temperature of the ampoule 320. For example, heating the ampoule 320 with a heater (not shown) may increase the concentration of volatized precursor 319 in order to allow for a higher concentration of the precursor gas species in the carrier gas/precursor mixture (i.e., the precursor gas 327) that exits the outlet 324 towards a photonic sensor and a processing chamber.

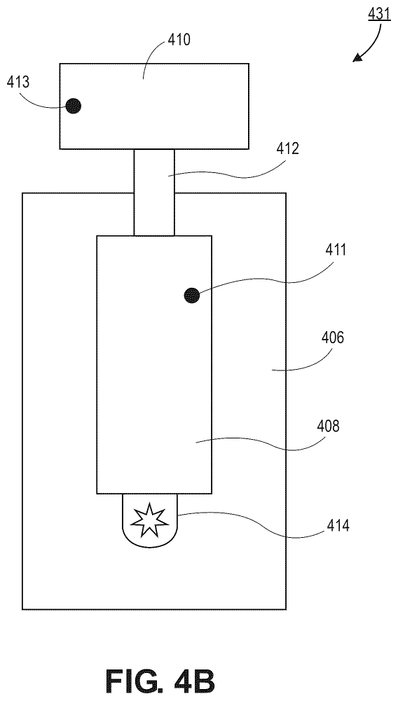

Accordingly, an improved NDIR optical absorption sensor may be implemented to perform vapor concentration sensing. That is, a concentration of a precursor species in a gas may be calculated through the use of an NDIR sensor. FIG. 4A provides a schematic illustration of such an NDIR system, in accordance with an embodiment.

Referring to FIG. 4A, an NDIR sensor 431 is shown, in accordance with an embodiment. In an embodiment, the NDIR sensor 431 comprises a photon source 402. For example, the photon source 402 may comprise an IR light source, an ultraviolet (UV) light source, or any other suitable source of electromagnetic radiation. A reflector may direct a greater portion of the IR radiation through the NDIR sensor 431. In an embodiment, the IR radiation may propagate along a gas cell-body 408. The gas cell-body 408 may be a hollow tube in some embodiments. The photon source 402 may be separated from the main gas flow path of the gas cell-body 408 by one or both of a window 406 or an optical filter. In some embodiments, the photon source 402 may be spaced away from the gas cell-body 408 and a fiber optic cable and/or other optics may optically couple the light source 402 to the gas cell-body 408. In an embodiment, a photonic detector system may be provided at an opposite end of the gas cell-body 408 from the light source 402. The photonic detector system may comprise an optical filter 419 and a photo-detector 414 after the optical filter 419. For example, the photo-detector 414 may be an IR photo-detector 414 (in the case an IR light source 402 is used) or a UV photo-detector 414 (in the case a UV light source 402 is used), or a photo-detector 414 for other wavelengths (in the case any other frequency light source 402 is used). In an embodiment, a printed circuit board (PCB) 416 may also be part of the photonic detector system. The PCB 416 may house a controller that comprises processing components, memory components, communication components, and/or the like. As will be described in greater detail below, the controller may implement dynamic correction processes in order to improve the performance and/or accuracy of the NDIR sensor 431. In an embodiment, the photonic detector system may also comprise a heatsink (not shown) that is thermally coupled to the photo-detector 414. While the photo-detector 414 is directly adjacent to the gas cell-body 408 in FIG. 4A, it is to be appreciated that optics lines (e.g., optical fibers, lenses, etc.) may be coupled to the gas cell-body 408 (or the filter 419) in order to transport the IR radiation to a photo-detector 414 that is spaced away from the gas cell-body 408. This may be beneficial for thermal control purposes, since the gas cell-body 408 is typically heated, and the photo-detector 414 is temperature sensitive.

In an embodiment an input 404 may be provided proximate to a first end of the gas cell-body 408, and an output 410 may be provided proximate to a second end of the gas cell-body 408. Gas that comprises species 415 (e.g., a precursor species) may flow into the gas cell-body 408 through the input 404, travel along a length of the gas cell-body 408, and exit the NDIR sensor 431 through the output 410. As the IR radiation propagates along the gas cell-body 408, the species 415 may absorb some of the IR radiation. This decreases the magnitude of the signal detected by the photo-detector 414. As described above, the change in magnitude of the signal can be used to determine a concentration of the species 415. In some embodiments, a pressure sensor 418 or pressure transducer may be coupled to one or more of the input 404, the gas cell-body 408, or the output 410.

Environmental temperature variations can lead to deviations in the accuracy of the concentration measurements in photonic sensors. Particularly, changes in the heat of the gas cell-body will result in changes to the background IR radiation. This can alter the readings of the photo-detector by providing uncontrolled amounts of IR radiation into the system. Additionally, changes to the temperature of the photo-detector can alter the amount of leakage current (or dark current). As such, the magnitude of the intensity signal will also be altered, and the measured concentration will deviate from an accurate reading.

Accordingly, embodiments include a photonic sensor with the added ability to account for these temperature changes. Generally, this is done by providing a temperature sensor on one or both of the gas cell-body or photonic detector system (e.g., on the heatsink). An example of such an embodiment is shown, in accordance with FIG. 4B.

Referring now to FIG. 4B, a schematic illustration of a photonic sensor 431 is shown, in accordance with an embodiment. In an embodiment, the photonic sensor 431 may be an NDIR sensor or the like. The photonic sensor 431 may comprise a light source 402, such as an IR light source. The light source 402 may be similar to any of the light sources or photon sources described in greater detail herein. The light source 402 may be coupled to a gas cell-body 408 so that the IR radiation propagates along a length of the gas cell-body 408 towards a photonic detector system 431. A connector 412 may couple the gas cell-body 408 to the photonic detector system 431 so that the photonic detector system 431 can be positioned outside of a temperature controlled housing 408 (e.g., a hot can). In an embodiment, the photonic detector system 431 may comprise a photo-detector, a controller, and a heat sink. The photonic detector system 431 may be similar to any of the photonic detector systems described in greater detail herein.

In an embodiment, the photonic sensor 431 may further comprise one or more temperature sensors. For example, a first temperature sensor 411 may be configured to measure a temperature of the gas cell-body 408 and a second temperature sensor 413 may be configured to measure a temperature of the photonic detector system 431. The first temperature sensor 411 may be directly contact an outer surface of the gas cell-body 408 in some embodiments. The second temperature sensor 413 may be provided on any of the components of the photonic detector system 431. In a particular embodiment, the second temperature sensor 413 is configured to measure a temperature of the heat sink, or the electronic circuit board (PCB) of the sensor. In such an embodiment, the second temperature sensor 413 may directly contact the heat sink. In an embodiment, the first temperature sensor 411 and the second temperature sensor 413 may include any suitable type of temperature sensor. For example, the temperature sensors 411 and 413 may comprise a resistance temperature detector (RTD), a thermocouple, or the like.

In an embodiment, the temperature sensors 411 and 413 may provide temperature readings that can be used to generate a calibration model that is applied to the intensity signal in order to dynamically correct the intensity signal in order to account for temperature variations in the environment. That is, the intensity value is corrected in order to obtain a calibrated absorbance, and the calibrated absorbance can then be used to determine a concentration of the species. In an embodiment, the calibration model may use one or more parameters in order to correct the absorbance signal. In an embodiment, each parameter may be a coefficient, an exponent, or the like within a term that includes the readings from one or both of the temperature sensors 411 and 413. These calibration models may be mathematical equations that are linear or non-linear. It is to be appreciated that single parameter solutions and multi-parameter solutions may both include linear or non-linear calibration models.

In an embodiment, a dynamic correction may be implemented through the use of mathematical modeling that can be used to find characteristic fit values for the one or more temperature readings from these additional temperature sensors. For example, a calibration model that is dependent on the readings of one or more of the temperature sensors is applied (e.g., through addition, subtraction, multiplication, division, etc.) to the intensity signal in order to provide the dynamic correction. The calibration model may be a linear function or a non-linear function of the temperature, depending on how many parameters are used and how the various terms are arranged in the mathematical models. In some instances, increasing the number of terms with the same parameters but in different algebraic combinations (such as, introducing exponential, logarithmic, correlation, or products of multiple parameters) in the calibration model may increase the resulting accuracy of the photonic sensor.

The ability to provide improved accuracy of species concentrations in the precursor gas delivered to the processing tool enables better model generation and subsequent monitoring through the use of virtual metrology since the input data has better accuracy. Generally, a model may be developed through training with a training data set. The training data set may comprise a plurality of film thickness values. The film thickness values may be measured with physical metrology. In an embodiment, each of the plurality of film thickness values may be correlated with a sensor data set. The sensor data set may include sensor readings from a plurality of sensors during the deposition of the film that was measured. For example, sensors similar to sensors 231-236 described above may be used in order to produce the data set. After the model is trained and validated, the model may be deployed in a production environment in order to implement virtual metrology on production substrates.

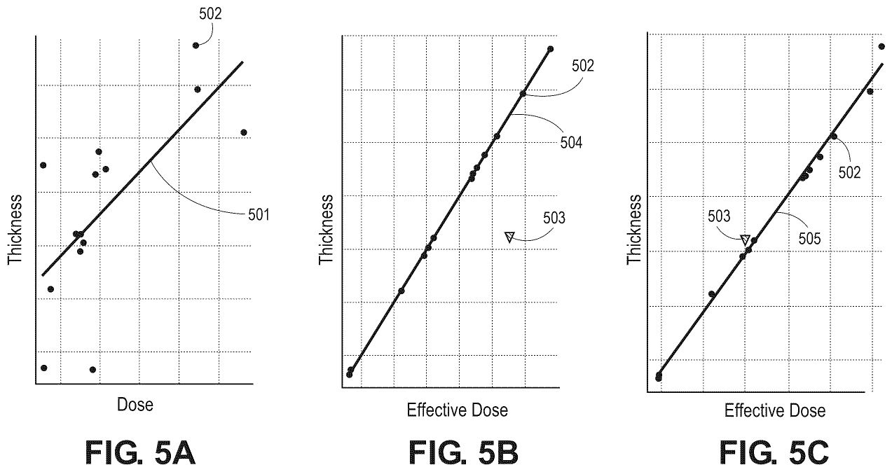

In order to generate a good model that is representative of the process being monitored, the right modeling approach should be taken. For example, FIG. 5A-5C illustrate three different approaches. In FIG. 5A, a linear fit line 501 is shown for a plurality of data points 502 that include a dose (X-axis) and a film thickness (Y-axis). As shown, the linear fit line 501 does not provide an accurate mapping of the data points, and the value of such a linear fit line 501 for virtual metrology is limited.

In FIG. 5B, the X-axis represents an “effective dose” and the Y-axis represents film thickness. The effective dose may represent the collective contribution of a plurality of variables that impact the film thickness. For example, the variables may include values recorded by one or more sensors in the processing tool (e.g., dose (i.e., precursor species concentration), carrier gas pressure, chuck heater temperature, chamber pressure, substrate backside gas flow, ampoule temperature, etc.). In the graph of FIG. 5B, a linear model 504 of the data set provides good prediction of the data set used to generate the linear model 504. However, subsequent testing (indicated with data point 503) shows a poor prediction. That is, the linear model 504 has over-fit the training data set. Accordingly, the linear model 504 also does not provide an accurate mapping of the data points for virtual metrology. While a linear model 504 is shown, similar results may also be observed when non-linear models are produced from the data set as well.

Referring now to FIG. 5C, the X-axis represents the effective dose, and the Y-axis represents film thickness. However, instead of a traditional regression approach, a machine learning approach is used to develop the machine learning model 505. As shown, the machine learning model 505 provides an excellent fit to the training data points 502 while also acting as a good predictor for subsequent testing (indicated with data point 503). As such, the machine learning model 505 is an accurate predictor of film thickness and can be used in subsequent virtual metrology in a production environment.

While various approaches are described with respect to FIG. 5A-5C, it is to be appreciated that any suitable machine learning approaches and/or algorithms may be used in conjunction with embodiments disclosed herein. For example, a neural network based approach may also be used to provide a prediction of film thickness in some embodiments. For example, an artificial neural network (ANN) may be used to predict a thickness of a layer deposited by the ALD process through analysis of sensor data. In an embodiment, the ANN may train the model by iteratively adjusting weights through backpropagation to minimize prediction errors. This allows for the effective capture of complex relationships in the data. In some embodiments, Monte Carlo simulations may be integrated with empirically calculated uncertainties in order to drive tighter confidence bands for the model. This may significantly reduce overlap compared to theoretical uncertainties.

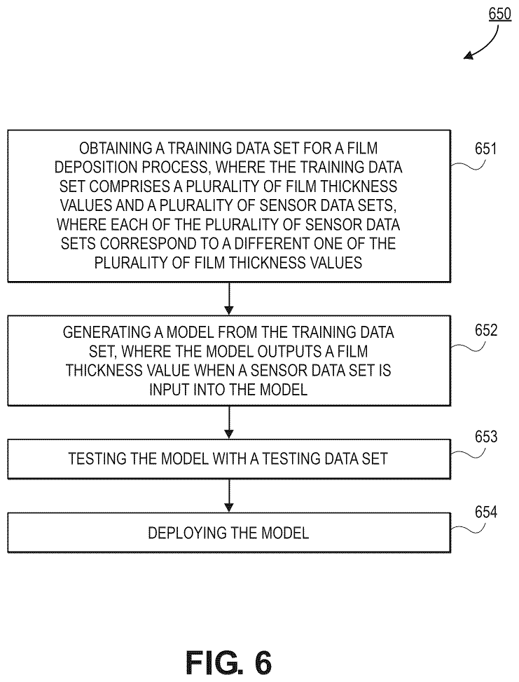

Referring now to FIG. 6, a flow diagram of a process 650 for training a model using machine learning to predict film thickness is shown, in accordance with an embodiment. In an embodiment, the process 650 may begin with operation 651, which comprises obtaining a training data set for a film deposition process. In an embodiment, the training data set may comprises a plurality of film thickness values. The film thickness values may be a measure of film thickness (as determined by physical metrology) of a plurality of substrates. In an embodiment, the training data set may also comprise a plurality of sensor data sets. Each of the sensor data sets may comprise a plurality of sensor readings from a plurality of sensors that record data during the deposition of a film on a substrate. In an embodiment, each film thickness value may be associated with a sensor data set. That is, each film thickness value may be associated with a plurality of sensor data readings that are obtained during the deposition process used to deposit the film that is measured to provide the film thickness value. Stated differently, the sensor data set may comprise a plurality of input data entries for a model, and the film thickness value associated with the particular sensor data set may be an output data entry for the model. In an embodiment, at least one of the plurality of sensors may comprise an NDIR optical absorption sensor that comprises a temperature sensor to allow for a dynamic correction of a concentration of species of a gas flown into the chamber.

In an embodiment, the process 650 may continue with operation 652, which comprises generating a model from the training data set. In an embodiment, the model outputs a film thickness value when a sensor data set is input into the model. In an embodiment, the model may include a machine learning model that is trained using at least a portion of the training data set. In an embodiment, the machine learning model may include any suitable machine learning algorithm. In one embodiment, the machine learning algorithm may include a gradient boosting algorithm or a random forest algorithm. Though, any suitable machine learning algorithm may be used in other embodiments disclosed herein. In some embodiments, the training process is model agnostic, and the algorithms search for the most suitable model based on the training data set that is used to train the model. Such models are less susceptible to the risk of over-fitting.

In an embodiment, the process 650 may continue with operation 653, which comprises testing the model with a testing data set. In an embodiment, the testing data set may be a subset of the training data set that was not used in order to train the machine learning model. Though, in other embodiments where data is plentiful, the model may be trained on training data and data used to confirm the model may be subsequent processing data.

In an embodiment, the process 650 may continue with operation 654, which comprises deploying the model. In an embodiment, the model may be deployed after the testing operation 653 provides satisfactory results that indicate good predictive outcomes with minimal over-fitting errors. Deploying the model may refer to using the model in a production environment in order to provide virtual metrology of subsequently processed substrates, as will be described in greater detail herein.

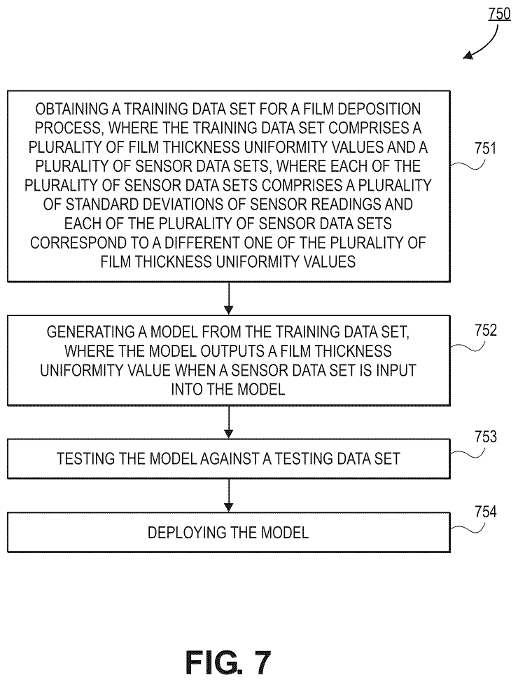

Referring now to FIG. 7, a flow diagram of a process 750 for training a model using machine learning to predict film thickness uniformity is shown, in accordance with an embodiment. In an embodiment, the process 750 may begin with operation 751, which comprises obtaining a training data set for a film deposition process. In an embodiment, the training data set may comprises a plurality of film thickness uniformity values. The film thickness uniformity values may be a measure of film thickness uniformity (as determined by physical metrology) of a plurality of substrates. In an embodiment, the training data set may also comprise a plurality of sensor data sets. Each of the sensor data sets may comprise a plurality of sensor readings from a plurality standard deviations of sensor readings that are recorded by a plurality of sensors during the deposition of a film on a substrate. In an embodiment, at least one of the plurality of sensors may comprise an NDIR optical absorption sensor that comprises a temperature sensor to allow for a dynamic correction of a concentration of species of a gas flown into the chamber. In an embodiment, each film thickness uniformity value may be associated with a sensor data set. That is, each film thickness uniformity value may be associated with a plurality of standard deviations of sensor data readings that are obtained during the deposition process used to deposit the film that is measured to provide the film thickness uniformity value. Stated differently, the sensor data set may comprise a plurality of input data entries for a model (i.e., sensor reading standard deviations), and the film thickness uniformity value associated with the particular sensor data set may be an output data entry for the model.

In an embodiment, the use of standard deviations of the sensor readings provides a quantitative measure of the variables. As a result, additional insight into causes of the non-uniformity of the deposited film can be obtained and used to provide better prediction of any non-uniformity of the film thickness. In an embodiment, the standard deviations of the sensor readings may refer to the standard deviation of a plurality of sensor readings from a single sensor during the deposition process for a film. For example, a sensor may record two or more readings, tens of readings, hundreds of readings, or thousands of readings during the deposition of a film onto a substrate. The standard deviation of those readings may be used as an entry into a sensor data set for the particular film.

In an embodiment, the process 750 may continue with operation 752, which comprises generating a model from the training data set. In an embodiment, the model outputs a film thickness uniformity value when a sensor data set is input into the model. In an embodiment, the model may include a machine learning model that is trained using at least a portion of the training data set. In an embodiment, the machine learning model may include any suitable machine learning algorithm. In one embodiment, the machine learning algorithm may include a gradient boosting algorithm or a random forest algorithm. Though, any suitable machine learning algorithm may be used in other embodiments disclosed herein. In some embodiments, the training process is model agnostic, and the algorithms search for the most suitable model based on the training data set that is used to train the model. Such models are less susceptible to the risk of over-fitting.

In an embodiment, the process 750 may continue with operation 753, which comprises testing the model with a testing data set. In an embodiment, the testing data set may be a subset of the training data set that was not used in order to train the machine learning model. For example, the testing data set may comprise up to approximately 10% of the data within the testing data set, or up to approximately 20% of the data within the testing data set. The testing process may be used to confirm that the machine learning model is not over-fit to the data used to train the machine learning model. In some embodiments, the model generation and model testing process may be an iterative process where the model is trained and tested a plurality of times. When an iterative process is used, the segmentation between “training data” and “testing data” may be different for different iterations of the process 750.

In an embodiment, the process 750 may continue with operation 754, which comprises deploying the model. In an embodiment, the model may be deployed after the testing operation 753 provides satisfactory results that indicate good predictive outcomes with minimal over-fitting errors. Deploying the model may refer to using the model in a production environment in order to provide virtual metrology of subsequently processed substrates, as will be described in greater detail herein.

In an embodiment, the deployment of machine learning generated models, such as those described in greater detail herein, may include the use of such models in order to implement virtual metrology during the production of semiconductor devices. The use of virtual metrology may allow for better optimization of the film deposition process. For example, careful control of the deposition process may allow for better and more efficient use of expensive precursor materials. Additionally, physical metrology can be significantly reduced. This can lead to higher throughputs and reduced device costs. Further, the ability to track film deposition conditions through virtual metrology allows for increased tool up-time. That is, process drift may be accounted for by automated changes to processing conditions in order to maintain film thickness properties within a desired threshold without needing to implement as many planned maintenance (PM) events.

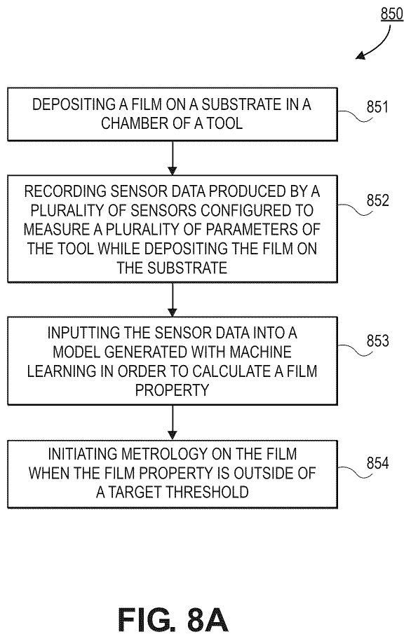

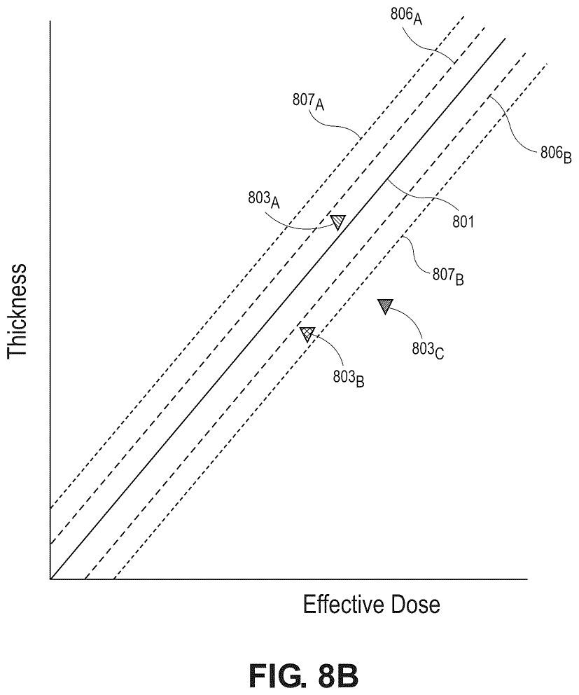

Referring now to FIG. 8A, a flow diagram of a process 850 for using a machine learning model to implement virtual metrology on a film is shown, in accordance with an embodiment. In an embodiment, the process 850 may begin with operation 851, which comprises depositing a film on a substrate in a chamber of a tool. In an embodiment, the tool may be similar to tool 200 described in greater detail herein. For example, a plurality of sensors may be coupled to the tool 200 to provide readings of various processing parameters during the deposition of the film. In an embodiment, at least one of the plurality of sensors may comprise an NDIR optical absorption sensor that comprises a temperature sensor to allow for a dynamic correction of a concentration of species of a gas flown into the chamber.

In an embodiment, the process 850 may continue with operation 852, which comprises recording sensor data produced by the plurality of sensors configured to measure a plurality of parameters of the tool while depositing the film on the substrate. In an embodiment, the plurality of parameters may include one or more of dose (i.e., precursor species concentration), carrier gas pressure, chuck heater temperature, chamber pressure, chamber backside gas flow, ampoule temperature, or the like. The sensor data may include a series of data obtained over the duration of the deposition of the film for each of the sensors. In some embodiments, the sensor data may include one or more of the totality of the recorded data for each sensor, an average of the recorded data for each sensor, a standard deviation of the recorded data for each sensor, or any other manipulation of the raw data from each sensor.

In an embodiment, the process 850 may continue with operation 853, which comprises inputting the sensor data into a model generated with machine learning in order to calculate a film property. In an embodiment, the model may be similar to any of the models described in greater detail herein and/or any combination of models described in greater detail herein. For example, the machine learning model may include a model formed with training that includes a gradient boosting algorithm or a random forest algorithm. The machine learning model may be used to calculate any suitable film property, such as film thickness and/or film thickness uniformity.

In an embodiment, operation 853 may sometimes be referred to as implementing virtual metrology. In some embodiments, the calculation of operation 853 may be implemented in real-time or in near real-time during the processing of the substrate. As such, a calculated film thickness value (e.g., film thickness or film thickness uniformity) can be determined for each of the substrates that are processed within a processing tool. In such an embodiment, better control of the deposition process (e.g., process uniformity between substrates, efficient use of precursors, higher chamber up-time, etc.) are enable through the process 850.

In some embodiments, the processing tool may drift over time and begin producing less reliable results. In such an embodiment, the process 850 may continue with operation 854, which comprises initiating physical metrology on the film when the film property is outside of a target threshold. For example, FIG. 8B illustrates a plot of effective dose (X-axis) to thickness (Y-axis). The solid line 801 represents the machine learning model, and the dashed lines 806_{A-B} and 807_{A-B} may represent threshold bands. In an embodiment, the band between line 806_{A} and 806_{B} may represent a green zone where there is no need for further investigation of the film property. For example, data point 803_{A} is in the green zone. The bands between line 806_{A} and 807_{A} or between line 806_{B} and 807_{B} may be yellow zones, where the film property is still within a given specification, but approaching a potential issue. For example, data point 803_{B} is in the yellow zone. Outside of the lines 807_{A} and 807_{B} may indicate red zone where a film property is outside of a given target threshold. For example, data point 803_{C} is in the red zone. For example the target threshold (e.g., lines 806_{A-B} or lines 807_{A-B}) may be within 5% of the machine learning model expected value, or within 10% of the machine learning model expected value.

In the embodiments disclosed herein, film deposition processes for semiconductor processing are described in detail. The output values for machine learning models directed to such processes are directed to film thickness values (e.g., film thickness and/or film thickness uniformity). However, embodiments are not limited to such virtual metrology. For example, film composition may also be monitored with machine learning models similar to those described herein. In such an embodiment, the training data set may include material composition of the film measured with physical metrology, and the sensor input data may then be mapped to the material composition data. In such a way, virtual metrology may be used to calculate film composition as well.

Similarly, other semiconductor manufacturing processes may be modeled with machine learning models, such as etching processes, treatment processes, doping processes, and/or the like. Accordingly, embodiments disclosed herein allow for virtual metrology of many different processes and/or parameters in order to provide enhanced control of a semiconductor processing environment.

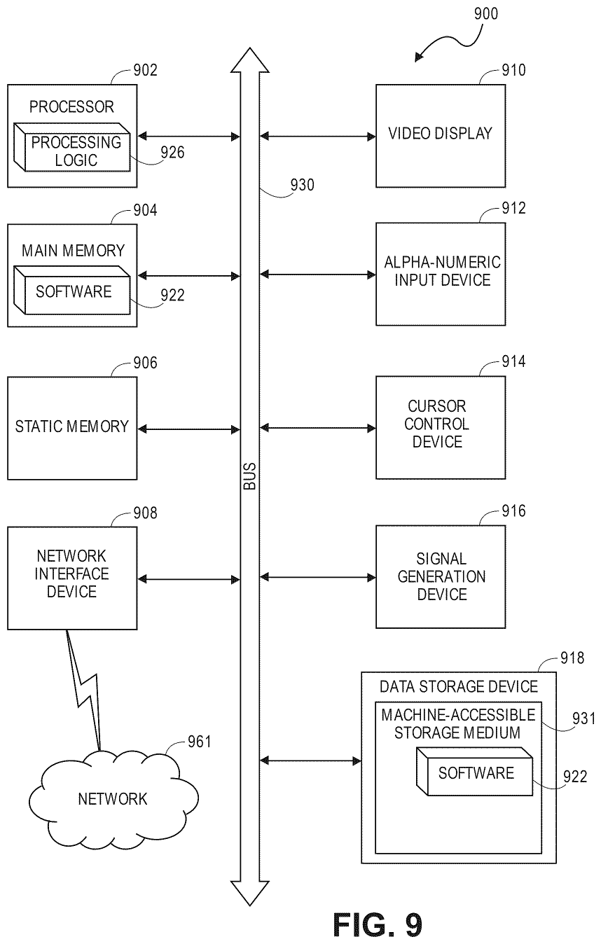

Referring now to FIG. 9, a block diagram of an exemplary computer system 900 of a processing tool is illustrated in accordance with an embodiment. In an embodiment, computer system 900 is coupled to and controls processing in the processing tool. The computer system 900 may be communicatively coupled to one or more vapor concentration sensor modules, such as those disclosed herein. The computer system 900 may utilize outputs from the one or more vapor concentration sensor modules in order to modify one or more parameters, such as, for example, processing recipe parameters, cleaning schedules for the processing tool, component replacement determinations, and the like.

Computer system 900 may be connected (e.g., networked) to other machines in a Local Area Network (LAN), ECAT, an intranet, an extranet, or the Internet. Computer system 900 may operate in the capacity of a server or a client machine in a client-server network environment, or as a peer machine in a peer-to-peer (or distributed) network environment. Computer system 900 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 900, the term “machine” shall also be taken to include any collection of machines (e.g., computers) that individually or jointly execute a set (or multiple sets) of instructions to perform any one or more of the methodologies described herein.

Computer system 900 may include a computer program product, or software 922, having a non-transitory machine-readable medium having stored thereon instructions, which may be used to program computer system 900 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 900 includes a system processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device, cloud storage), which communicate with each other via a bus 930.

System processor 902 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 902 may also be one or more special-purpose processing devices such as an application specific integrated circuit (ASIC), a field programmable gate array (FPGA), a digital signal processor (DSP) system, network system processor, or the like. System processor 902 is configured to execute the processing logic 926 for performing the operations described herein.

The computer system 900 may further include a system network interface device 908 for communicating with other devices or machines. The computer system 900 may also include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium 931 (or more specifically a computer-readable storage medium) on which is stored one or more sets of instructions (e.g., software 922) embodying any one or more of the methodologies or functions described herein. The software 922 may also reside, completely or at least partially, within the main memory 904 and/or within the system processor 902 during execution thereof by the computer system 900, the main memory 904 and the system processor 902 also constituting machine-readable storage media. The software 922 may further be transmitted or received over a network 961 via the system network interface device 908. In an embodiment, the network interface device 908 may operate using RF coupling, optical coupling, acoustic coupling, or inductive coupling.

While the machine-accessible storage medium 931 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. A method, comprising:
obtaining a training data set for a film deposition process, wherein the training data set comprises:
a plurality of film thickness values; and
a plurality of sensor data sets, wherein each of the plurality of sensor data sets correspond to a different one of the plurality of film thickness values;
generating a model from the training data set, wherein the model outputs a film thickness value when a sensor data set is input into the model; and
testing the model with a testing data set.

2. The method of claim 1, wherein each of the plurality of sensor data sets comprise sensor readings from a plurality of sensors coupled to a chamber, wherein the chamber is used to implement the film deposition process.

3. The method of claim 2, wherein the plurality of sensors comprises a non-dispersive infrared (NDIR) optical absorption sensor.

4. The method of claim 3, wherein the NDIR optical absorption sensor comprises a temperature sensor to allow for a dynamic correction of a concentration of species of a gas flown into the chamber.

5. The method of claim 1, wherein the model is generated with a gradient boosting algorithm or a random forest algorithm.

6. The method of claim 1, wherein the testing data set is a subset of the training data set that is not used while generating the model.

7. A method, comprising:
obtaining a training data set for a film deposition process, wherein the training data set comprises:
a plurality of film thickness uniformity values; and
a plurality of sensor data sets, wherein each of the plurality of sensor data sets comprises a plurality of standard deviations of sensor readings, and wherein each of the plurality of sensor data sets correspond to a different one of the plurality of film thickness uniformity values; and
generating a model from the training data set, wherein the model outputs a film thickness uniformity when a sensor data set is input into the model.

8. The method of claim 7, wherein the plurality of standard deviation of sensor readings for each of the plurality of sensor data sets are obtained from sensor readings produced by a plurality of sensors coupled to a chamber, wherein the chamber is used to implement the film deposition process.

9. The method of claim 8, wherein the plurality of sensors comprises a non-dispersive infrared (NDIR) optical absorption sensor.

10. The method of claim 9, wherein the NDIR optical absorption sensor comprises a temperature sensor to allow for dynamic correction of a concentration of species of a gas flown into the chamber.

11. The method of claim 7, wherein the model is generated with a gradient boosting algorithm or a random forest algorithm.

12. The method of claim 7, wherein the testing data set is a subset of the training data set that is not used while generating the model.

13. A method, comprising:
depositing a film on a substrate in a chamber of a tool;
recording sensor data produced by a plurality of sensors configured to measure a plurality of parameters of the tool while depositing the film on the substrate; and
inputting the sensor data into a model generated with machine learning in order to calculate a film property.

14. The method of claim 13, wherein the plurality of sensors comprises a non-dispersive infrared (NDIR) optical absorption sensor.

15. The method of claim 14, wherein the NDIR optical absorption sensor comprises a temperature sensor to allow for a dynamic correction of a concentration of species of a gas flown into the chamber.

16. The method of claim 13, wherein the model is generated with a gradient boosting algorithm or a random forest algorithm.

17. The method of claim 13, wherein the film property is a film thickness.

18. The method of claim 13, wherein the film property is a film thickness uniformity.

19. The method of claim 13, further comprising:
initiating metrology on the film when the film property is outside of a target threshold.

20. The method of claim 13, wherein the plurality of parameters of the tool comprises one or more of a precursor gas species concentration, a carrier gas pressure, a heater temperature, a chamber pressure, a backside gas flow rate, or a temperature of an ampoule for storing a liquid precursor.
